(19) United States
(12) Patent Application Publication
(10) Pub. No.: US 2024/0332140 A1
(43) Pub. Date: Oct. 3, 2024

(54) LEAD FRAME AND SEMICONDUCTOR DEVICE

(71) Applicant: SHINKO ELECTRIC INDUSTRIES CO., LTD., Nagano (JP)

(72) Inventor: Kesayuki SONEHARA, Nagano (JP)

(21) Appl. No.: 18/612,186

(22) Filed: Mar. 21, 2024

(30) Foreign Application Priority Data
Mar. 28, 2023 (JP) 2023-051045

(51) Int. Cl. H01L 23/495; H01L 21/48; H01L 23/00

(52) U.S. Cl. CPC H01L 23/49551; H01L 21/4828; H01L 21/4842; H01L 23/49513; H01L 23/49568; H01L 24/48; H01L 2224/48101; H01L 2224/48105; H01L 2224/48245; H01L 2924/182

(57) ABSTRACT

A lead frame includes a die pad having an upper surface and a lower surface, and a curved part disposed outside the die pad in a bottom view, and having one end connected to an outer edge of the die pad. The curved part has a groove that opens toward the lower surface of the die pad, and the curved part is curved toward the upper surface of the die pad at the groove.

### CROSS-REFERENCE TO RELATED APPLICATIONS

This application is based upon and claims priority to Japanese Patent Application No. 2023-051045, filed on Mar. 28, 2023, the entire contents of which are incorporated herein by reference.

### FIELD

Certain aspects of the embodiments discussed herein are related to lead frames, semiconductor devices, and methods for manufacturing the lead frames.

### BACKGROUND

A known semiconductor device includes a semiconductor chip mounted on a lead frame and encapsulated by a resin. Such a semiconductor device may have a structure in which a lower surface of a die pad mounted with the semiconductor chip is exposed from the resin, so as to increase dissipation of heat generated during operation of the semiconductor chip. The lead frame used for assembling such a semiconductor device is bent so as to dispose the die pad at a lowermost portion, so that the lower surface of the die pad is exposed from the resin when the lead frame encapsulated by the resin, as proposed in Japanese Laid-Open Patent Publication No. 2010-165777, for example.

However, when bending the die pad and a part connected to an outer edge of the die pad, a flatness of the die pad may deteriorate due to stress caused by the bending. When the flatness of the die pad deteriorates, the resin may leak toward the lower surface of the die pad when manufacturing the semiconductor device by encapsulating the lead frame with the resin, for example.

### SUMMARY

In view of the problem described above, one object of the present disclosure is to improve a flatness of a die pad in a lead frame having a curved part connected to an outer edge of the die pad.

According to embodiments of the present disclosure, a lead frame includes a die pad having an upper surface and a lower surface; and a curved part disposed outside the die pad in a bottom view, and having one end connected to an outer edge of the die pad, wherein the curved part has a groove that opens toward the lower surface of the die pad, and the curved part is curved toward the upper surface of the die pad at the groove.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a top view illustrating an example of an entire lead frame according to a first embodiment;

FIG. 2 is a top view illustrating an example of a vicinity of one singulation region of the lead frame according to the first embodiment;

FIG. 3 is a bottom view illustrating an example of the vicinity of one singulation region of the lead frame according to the first embodiment;

FIG. 4A and FIG. 4B are cross sectional views illustrating examples of the vicinity of the singulation region illustrated in FIG. 2;

FIG. 5 is an enlarged view of a portion R illustrated in in FIG. 3;

FIG. 6 is a diagram illustrating an example of a manufacturing process of the lead frame according to the first embodiment;

FIG. 7A and FIG. 7B are cross sectional views illustrating examples of the vicinity of the singulation region illustrated in FIG. 6;

FIG. 8A and FIG. 8B are cross sectional views illustrating an example of a semiconductor device according to the first embodiment;

FIG. 9 is a bottom view illustrating the example of the semiconductor device according to the first embodiment;

FIG. 10A, FIG. 10B, FIG. 10C, and FIG. 10D are diagrams illustrating examples of manufacturing processes of the semiconductor device according to the first embodiment;

FIG. 11 is a partial bottom view illustrating an example of the lead frame according to a first modification of the first embodiment;

FIG. 12 is a bottom view illustrating an example of the semiconductor device according to the first modification of the first embodiment;

FIG. 13A and FIG. 13B are diagrams illustrating an example of the semiconductor device according to a second modification of the first embodiment;

FIG. 14 is a bottom view illustrating an example of the semiconductor device according to a third modification of the first embodiment;

FIG. 15 is a bottom view illustrating an example of the semiconductor device according to a fourth modification of the first embodiment; and

FIG. 16A and FIG. 16B are diagrams illustrating an example of semiconductor device according to a fifth modification of the first embodiment.

### DESCRIPTION OF EMBODIMENTS

Hereinafter, embodiments of the present disclosure will be described with reference to the drawings. In the drawings, the same constituent elements are designated by the same reference numerals, and a redundant description thereof may be omitted.

### First Embodiment

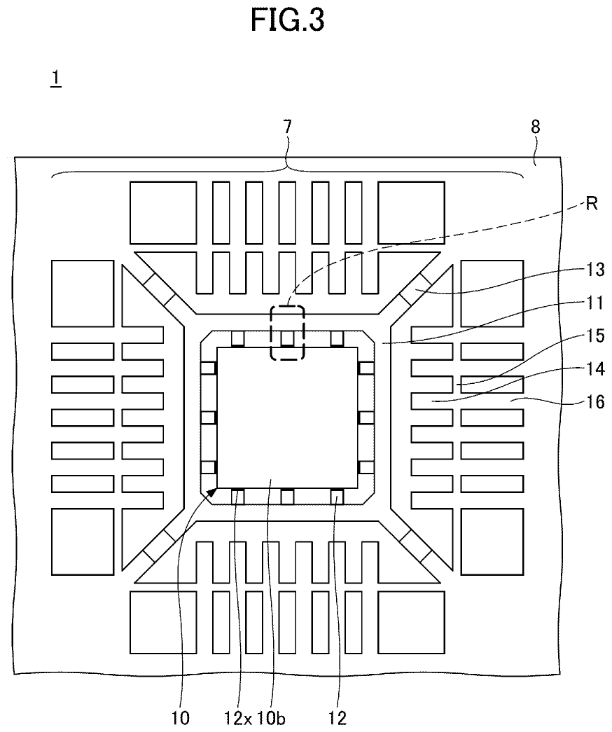

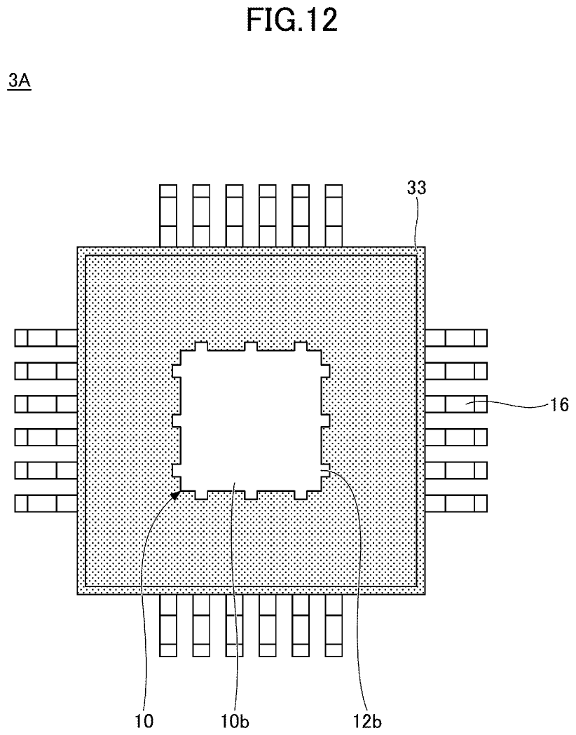

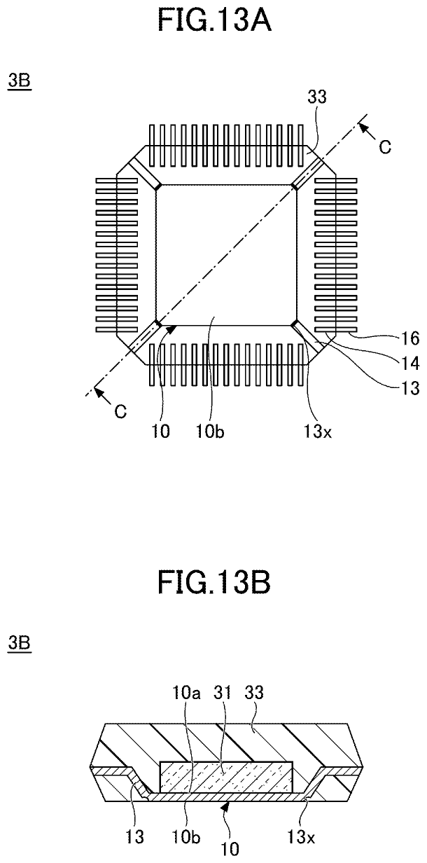

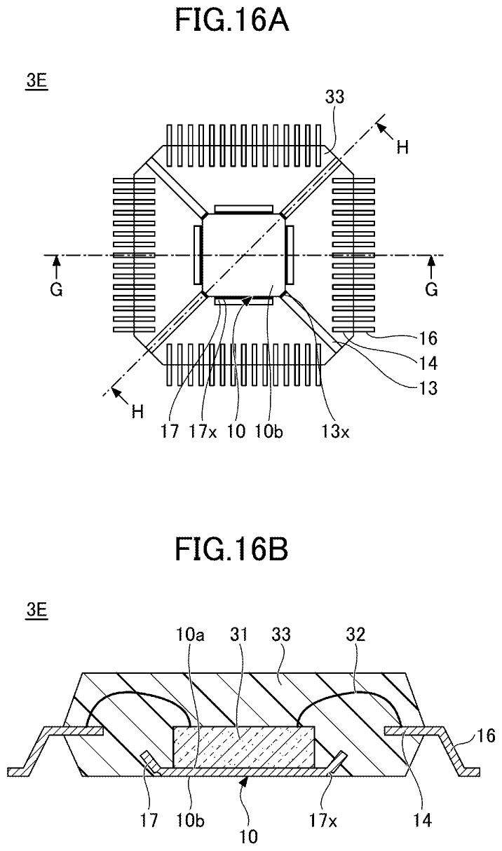

A lead frame according to the present disclosure includes a frame, a die pad having an upper surface and a lower surface and disposed inside the frame in a top view, and a curved part disposed outside the die pad in a bottom view and having one end connected to a portion of an outer edge of the die pad. The curved part refers to a part, that connects to the portion of the outer edge of the die pad in the bottom view, and curves toward the upper surface of the die pad. For example, a connecting part 12 illustrated in FIG. 3, a support bar 13 illustrated in FIG. 13A and FIG. 13B, a bend part 17 illustrated in FIG. 16A and FIG. 16B, or the like, which will be described later, are examples of the curved part. Hereinafter, a lead frame 1, which is an example of the lead frame according to the present disclosure, will be described.

### Structure of Lead Frame

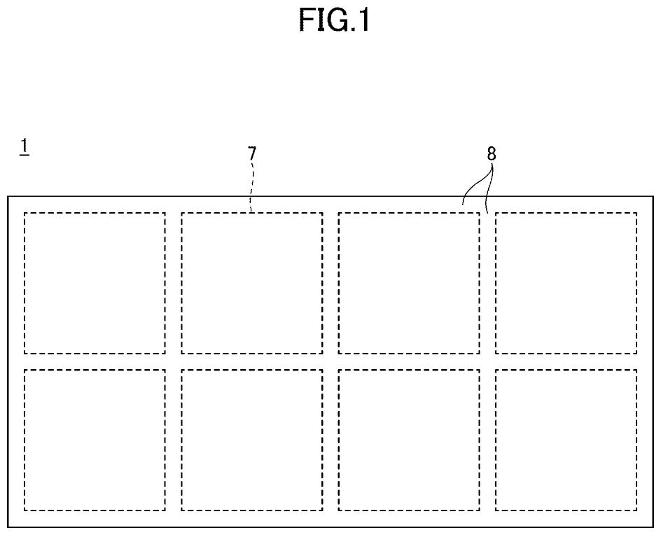

FIG. 1 is a top view illustrating an example of an entire lead frame according to a first embodiment. As illustrated in FIG. 1, a lead frame 1 includes singulation regions 7 and a frame 8. A material used for the lead frame 1 may be copper (Cu), a copper alloy, a 42 alloy, or the like, for example. A thickness of the lead frame 1 may be in a range greater than or equal to 124 μm and less than or equal to 250 μm, for example.

Each of the singulation regions 7 is a region (or area) surrounded and indicated by a broken line, and is finally cut and separated from the frame 8 (that is, singulated) to form a part of a semiconductor device. Although the singulation regions 7 are simplified and illustrated as having a rectangular shape in FIG. 1, the singulation regions 7 are not necessarily rectangular, and may have a more complex shape according to a shape of the semiconductor device.

The frame 8 includes a region provided in a picture-frame shape at an outer edge portion of the lead frame 1, and regions connected perpendicularly to each other inside the picture-frame shaped region and arranged in a lattice shape in between the singulation regions 7. In FIG. 1, the singulation regions 7 are arranged two dimensionally, but the singulation regions 7 may be arranged one dimensionally.

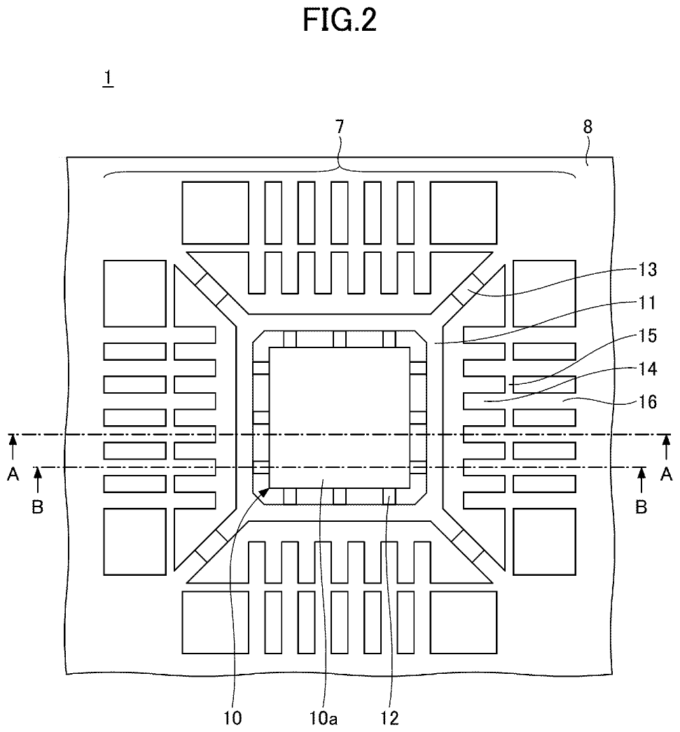

FIG. 2 is a top view illustrating an example of a vicinity of one singulation region of the lead frame according to the first embodiment. FIG. 3 is a bottom view illustrating an example of the vicinity of the one singulation region of the lead frame according to the first embodiment.

As illustrated in FIG. 2 and FIG. 3, a rectangular die pad 10 is disposed at a center of the singulation region 7. The die pad 10 has an upper surface 10a and a lower surface 10b. A ground ring 11 having an approximately rectangular picture-frame shape is arranged around the die pad 10 with a predetermined gap formed between the ground ring 11 and the die pad 10. The die pad 10 and the ground ring 11 are connected to each other via a plurality of connecting parts 12 that are arranged at predetermined intervals. In the top view and the bottom view, one end of the connecting part 12 is connected to a portion of a side forming the outer edge of the die pad 10, and the other end of the connecting part 12 is connected to a side of the ground ring 11 beside the die pad 10. The top view refers to a view from above in a normal direction to the upper surface 10a of the die pad 10, and the bottom view refers to a view from below in a normal direction to the lower surface 10b of the die pad 10.

Support bars 13 extend outward at four corners of the ground ring 11, respectively. The support bars 13 are connected to the frame 8. Accordingly, the die pad 10 and the ground ring 11 are connected to the frame 8 and supported by the connecting parts 12 and the support bars 13.

A plurality of inner leads 14 are provided outside the ground ring 11, so as to extend outward in a state separated from the ground ring 11. In the top view, the plurality of inner leads 14 extend in directions perpendicular to the corresponding sides on the outer side of the ground ring 11, for example.

Each inner lead 14 of the plurality of the inner leads 14 is connected to a dam bar 15. A plurality of outer leads 16 are connected to the dam bar 15 to extend outside the dam bar 15, in correspondence with the plurality of inner leads 14, respectively. In the top view, the dam bar 15 extends in a direction parallel to the corresponding side on the outer side of the ground ring 11, for example.

In the top view, the plurality of inner leads 14 and the plurality of outer leads 16 extend in the directions perpendicular to the corresponding sides on the outer side of the ground ring 11, for example. The dam bars 15 and the outer leads 16 are connected to and supported by the frame 8. The inner leads 14 are supported by the frame 8 via the dam bars 15 and the outer leads 16.

An upper surface of the ground ring 11 and an upper surface of the inner leads 14 can be used as wire bonding regions (or areas). For this reason, a metal plating layer for wire bonding, composed of silver (Ag) or nickel (Ni)/palladium (Pd) or the like, may be partially formed on the upper surface of the ground ring 11 and on the upper surface of the inner leads 14. The metal plating layer may be provided on a side surface of the ground ring 11 and on a side surface of the inner leads 14.

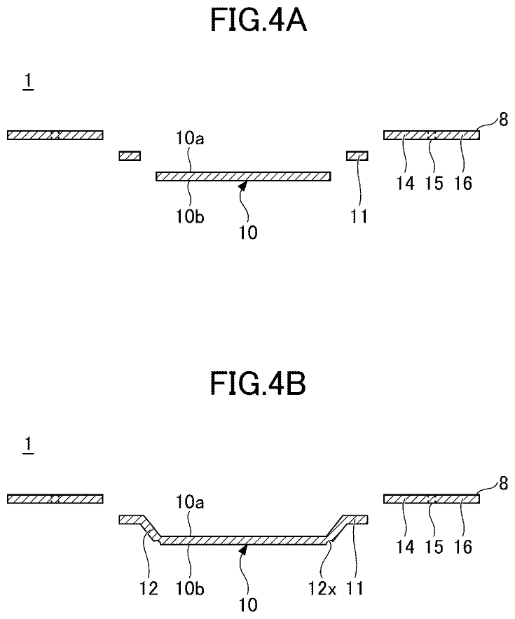

FIG. 4A and FIG. 4B are cross sectional views illustrating examples of the vicinity of the singulation region. FIG. 4A illustrates a cross section taken along a line A-A in FIG. 2, and FIG. 4B illustrates a cross section taken along a line B-B in FIG. 2.

As illustrated in FIG. 4A and FIG. 4B, the connecting part 12 that connects the die pad 10 and the ground ring 11 is bent and inclined at a portion connecting to the die pad 10 and bent at a portion connecting to the ground ring 11. The ground ring 11 is disposed at a position above the die pad 10. The support bar 13 connecting the ground ring 11 and the frame 8 is also bent and inclined. The inner leads 14, the dam bars 15, and the outer leads 16 are arranged at positions above the ground ring 11.

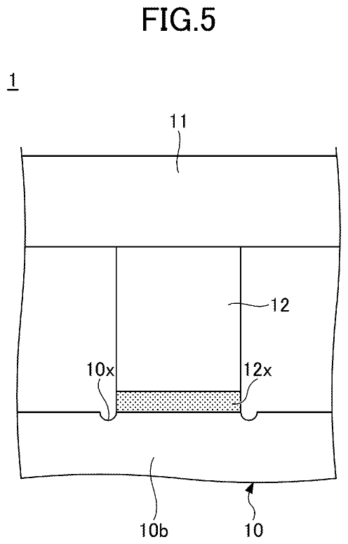

FIG. 5 is an enlarged view of a portion R illustrated in FIG. 3. As illustrated in FIG. 3 through FIG. 5, each connecting part 12 is provided with a groove 12x that opens toward the lower surface 10b of the die pad 10. The groove 12x is provided at the end portion of the connecting part 12 where the connecting part 12 connects to the die pad 10, so as to extend along each side forming the outer edge of the die pad 10 in the bottom view. That is, in the bottom view, the end portion of the groove 12x beside the die pad 10 is located on the side forming the outer edge of the die pad 10 to which the connecting part 12 is connected. The groove 12x is preferably provided for the entirety of the connecting part 12 along a width direction thereof, in a direction parallel to each side of the die pad 10 in the bottom view. In FIG. 5, the groove 12x is illustrated by a dot pattern for the sake of convenience.

A width of the groove 12x in a transverse direction when viewed in the normal direction to a lower surface of the connecting part 12 may be in a range greater than or equal to 10 μm and less than or equal to a thickness of the lead frame 1. The width of the groove 12x in the transverse direction is 20 μm, for example. A depth of a deepest portion of the groove 12x with reference to the lower surface of the connecting part 12 can be in a range greater than or equal to 5 μm and less than or equal to one-half the thickness of the lead frame 1. The depth of the deepest portion of the groove 12x is 10 μm, for example. The groove 12x may have an arbitrary cross sectional shape, but for example, the cross sectional shape may be an approximate V shape when the groove 12x is formed by press working, and may have an approximate U shape when the groove 12x is formed by etching.

Each connecting part 12 is bent toward the upper surface 10a of the die pad 10 at the end portion of the groove 12x beside the die pad 10, for example. An angle of bend of the connecting part 12 with reference to the lower surface 10b of the die pad 10 may be in a range of approximately 30 degrees to approximately 60 degrees, for example. By providing the groove 12x in the connecting part 12, it is possible to improve a flexibility of the connecting part 12 with respect to the die pad 10, as will be described hereinafter. From a viewpoint of improving the flexibility, in the case where the lead frame 1 has a plurality of connecting parts 12, it is preferable to provide the groove 12x in all of the plurality of connecting parts 12.

In general, during a bending process, an inner side of a bending portion is compressed, while an outer side of the bending portion is subjected to tensile stress. For this reason, the outer side of the bending portion is formed into a round shape by the tensile stress, and may easily become sagged (dented). For example, when the die pad sags, the resin leaks toward the lower surface of the die pad when the lead frame is encapsulated by the resin during the process of manufacturing the semiconductor device, and a poor external appearance or the like of the semiconductor device occurs. In addition, because an area of the lower surface of the die pad exposed from the resin decreases, heat dissipation of the semiconductor device deteriorates.

For example, the problem described above is likely to occur when no measures are taken at the bending portion between the die pad 10 and the connecting part 12 of the lead frame 1. Hence, in the lead frame 1, the groove 12x is provided in the connecting part 12, thereby reducing the possibility of such a problem from occurring.

That is, in the lead frame 1, the groove 12x is provided in advance in a portion of the connecting part 12, which becomes the outer side of the bending portion of the connecting part 12 during the process of bending the connecting part 12. Hence, the groove 12x becomes a starting point with respect to the tensile stress generated in the connecting part 12 during the bending process, and the connecting part 12 bends sharply with respect to the lower surface 10b of the die pad 10 at the end portion of the groove 12x beside the die pad 10. As a result, the outer side of the bending portion of the connecting part 12 is unlikely to have a round shape. In addition, sagging of the outer side of the bending portion of the connecting part 12 is also less likely to occur. Accordingly, the lower surface 10b of the die pad 10 can maintain the flatness of the entirety thereof including the end portion beside the connecting part 12. The improved flatness of the lower surface 10b of the die pad 10 can reduce the possibility of the resin leaking toward the lower surface 10b of the die pad 10 when the lead frame 1 is encapsulated by the resin during the process of manufacturing the semiconductor device.

As illustrated in FIG. 5, in the bottom view, a recess 10x, that is recessed toward the center of the die pad 10, may be provided on both sides of a region connecting to the connecting part 12 on the side forming the outer edge of the die pad 10. The recess 10x may be provided to penetrate the die pad 10 in the thickness direction. By providing the recess 10x, the bending process can easily be performed. The recess 10x can be used as a clearance for a mold that is used for the bending process, for example.

Because a bend is also formed between the connecting part 12 and the ground ring 11, a groove that opens toward the upper surface 10a of the die pad 10 may be provided at the end portion of the connecting part 12 beside the ground ring 11 (that is, between the connecting part 12 and the ground ring 11). In this case, a recess corresponding to the recess 10x may be provided in the ground ring 11.

### Method for Manufacturing Lead Frame

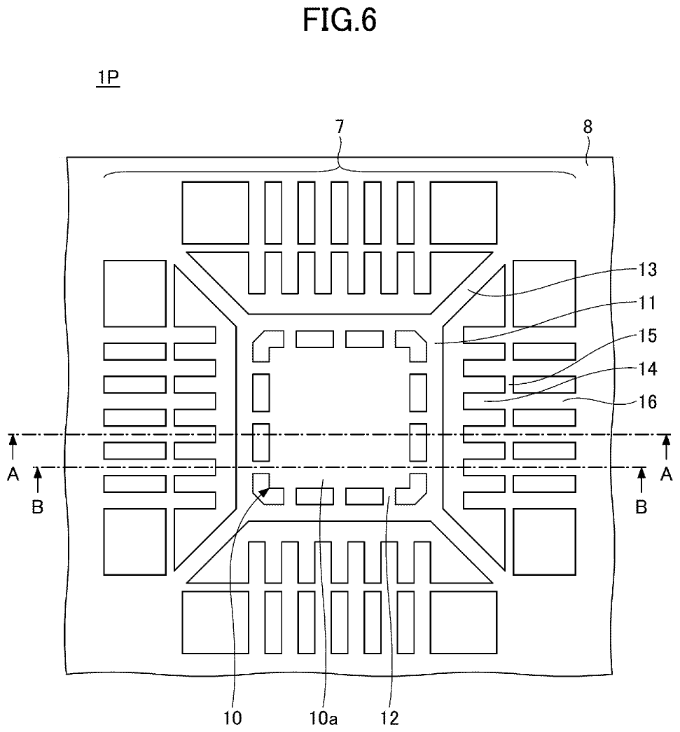

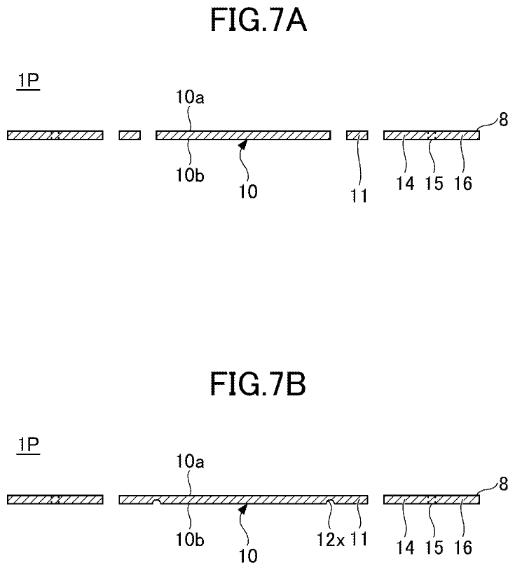

Next, a method for manufacturing the lead frame according to the first embodiment will be described. FIG. 6 is a diagram illustrating an example of the manufacturing process of the lead frame according to the first embodiment, and is a top view illustrating a vicinity of one singulation region of the lead frame. FIG. 7A and FIG. 7B are cross sectional views illustrating examples of the vicinity of the singulation region. FIG. 7A illustrates a cross section taken along a line A-A in FIG. 6, and FIG. 7B illustrates a cross section taken along a line B-B in FIG. 6. Positions of the line A-A and the line B-B in FIG. 6 correspond to the positions of the line A-A and the line B-B in FIG. 2, respectively.

In the process illustrated in FIG. 6, FIG. 7A, and FIG. 7B, a metal plate machining is performed to form a patterned metal plate 1P. FIG. 6, FIG. 7A, and FIG. 7B illustrate the patterned metal plate 1P after the metal plate machining. More particularly, first, the metal plate having a predetermined shape is prepared. Examples of a material used for the metal plate include copper (Cu), a copper alloy, a 42 alloy, or the like, for example. A thickness of the metal plate can be in a range greater than or equal to 124 μm and less than or equal to 250 μm, for example. Then, the metal plate is subjected to press working to form the patterned metal plate 1P. Alternatively, the metal plate is subjected to etching to form the patterned metal plate 1P.

The patterned metal plate 1P illustrated in FIG. 6, FIG. 7A, and FIG. 7B includes the frame 8, the die pad 10 having the upper surface 10a and the lower surface 10b and disposed inside the frame 8, the connecting parts 12 disposed outside the die pad 10 in the bottom view and having one end connected to a portion of the outer edge of the die pad 10, respectively, or the like. More particularly, the die pad 10 having the rectangular shape is disposed at a center of the patterned metal plate 1P, and the ground ring 11 having the approximately rectangular picture-frame shape is disposed around the die pad 10 with the predetermined gap formed between the ground ring 11 and the die pad 10. The die pad 10 and the ground ring 11 are connected to each other by the plurality of connecting parts 12 arranged at predetermined intervals. The support bars 13 extend outward from the four corners of the ground ring 11, respectively, and the support bars 13 are connected to the frame 8. Further, the plurality of inner leads 14 are provided outside the ground ring 11 so as to extend outward in a state separated from the ground ring 11. Each inner lead 14 is connected to the dam bar 15, and the plurality of outer leads 16 are connected to the dam bar 15 to extend outside the dam bar 15, in correspondence with the plurality of inner leads 14, respectively. The dam bars 15 are connected to and supported by the frame 8, and the plurality of outer leads 16 are connected to and supported by the frame 8.

Each connecting part 12 is provided with a groove 12x that opens toward the lower surface 10b of the die pad 10. The groove 12x can be formed simultaneously with other portions, when the press working or the etching is performed to form the patterned metal plate 1P. After the patterned metal plate 1P having no groove 12x is formed, the groove 12x may be formed in the patterned metal plate 1P by the press working or etching of another process performed before the bending process.

After the process illustrated in FIG. 6, FIG. 7A, and FIG. 7B, the patterned metal plate 1P is bent. That is, the connecting parts 12 connecting the die pad 10 and the ground ring 11 are bent, and the support bars 13 connecting the ground ring 11 and the frame 8 are bent, so that the patterned metal plate 1P becomes a stepped shape illustrated in FIG. 4B. The connecting parts 12 and the support bars 13 may be bent simultaneously in a single bending process. During this bending process, each connecting part 12 is bent to curve toward the upper surface 10a of the die pad 10, at the end portion of the groove 12x beside the die pad 10.

### Semiconductor Device

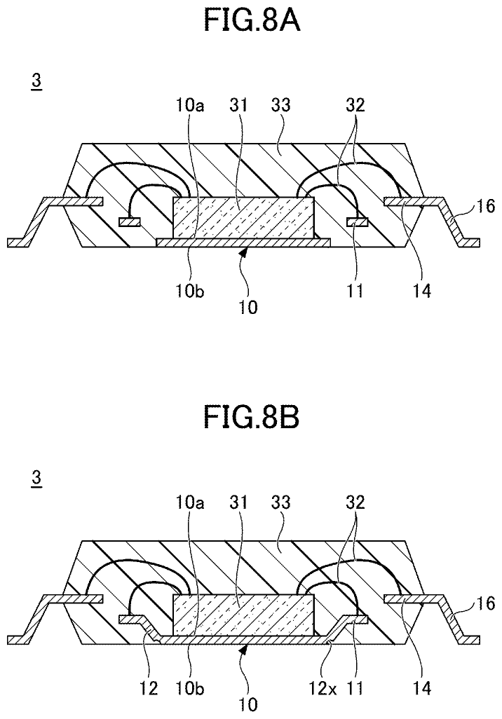

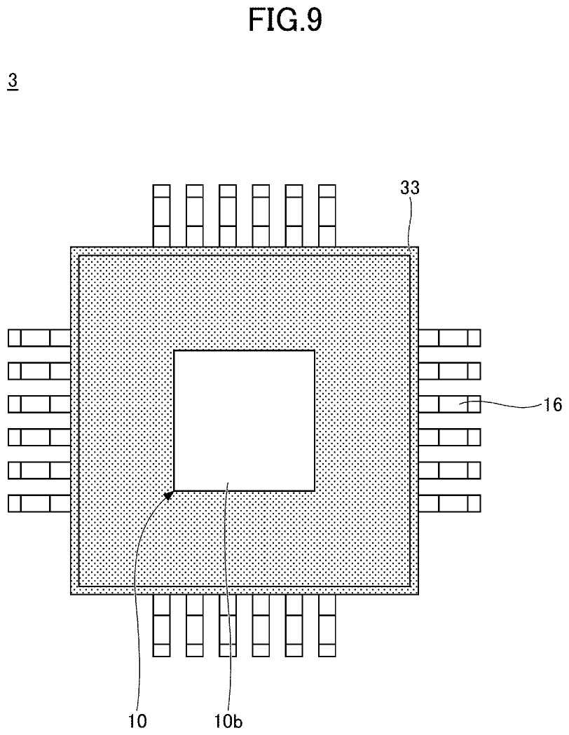

FIG. 8A and FIG. 8B are cross sectional views illustrating an example of a semiconductor device according to the first embodiment. FIG. 8A illustrates a cross section corresponding to FIG. 4A, and FIG. 8B illustrates a cross section corresponding to FIG. 4B. FIG. 9 is a bottom view illustrating the example of the semiconductor device according to the first embodiment.

As illustrated in FIG. 8A, FIG. 8B, and FIG. 9, a semiconductor device 3 includes the die pad 10, the ground ring 11, the connecting parts 12, the inner leads 14, the outer leads 16, a semiconductor chip 31, metal wires 32, and a resin part 33. In FIG. 9, the resin part 33 is illustrated by a dot pattern for the sake of convenience.

The metal wires 32 are gold wires, copper wires, or the like used for wire bonding, for example. The resin part 33 is a mold resin, for example. The mold resin is an insulating resin including, as a main component thereof, a non-photosensitive thermosetting resin which can be used for transfer molding, compression molding, injection molding, or the like, for example. The mold resin is an insulating resin, such as a non-photosensitive thermosetting epoxy resin, for example, and includes a filler.

The semiconductor device 3 is manufactured using the lead frame according to the first embodiment. That is, in the semiconductor device 3, the die pad 10, the ground ring 11, the connecting parts 12, the inner leads 14, and the outer leads 16 are manufactured from one singulation region 7 of the lead frame 1.

The semiconductor chip 31 is mounted on the upper surface 10a of the die pad 10. The resin part 33 encapsulates the semiconductor chip 31, the metal wires 32, the ground ring 11, and the inner leads 14. The outer leads 16 are exposed from the resin part 33. In addition, the lower surface 10b of the die pad 10 is exposed from the resin part 33. The grooves 12x are covered with the resin part 33.

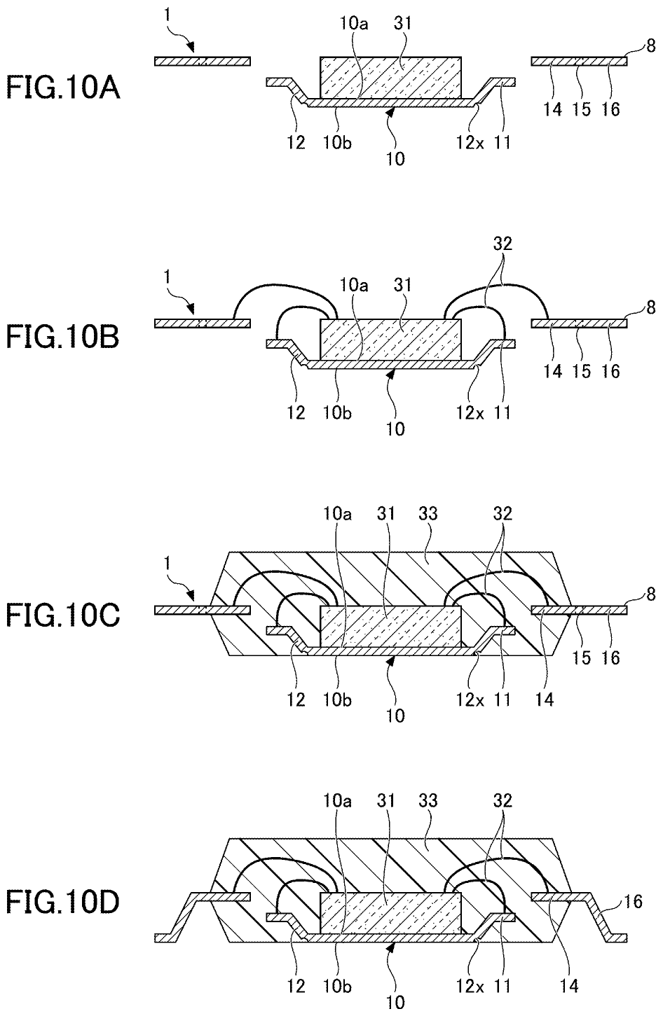

In order to manufacture the semiconductor device 3, the lead frame 1 is prepared, as illustrated in FIG. 10A. Then, the semiconductor chip 31 is fixed to the upper surface 10a of the die pad 10 using an adhesive, with connection electrodes of the semiconductor chip 31 facing upward. Thereafter, as illustrated in FIG. 10B, the connection electrodes of the semiconductor chip 31 are connected to the ground ring 11 and the inner leads 14 using the metal wires 32.

Next, as illustrated in FIG. 10C, the resin part 33 is formed to encapsulate the semiconductor chip 31, the metal wires 32, the ground ring 11, and the inner leads 14. In this case, the resin part 33 is formed so that the lower surface 10b of the die pad 10 and the outer leads 16 are exposed.

Further, the frame 8 is cut off from the lead frame 1, and the dam bars 15 are cut, thereby obtaining the plurality of separated inner leads 14 and outer leads 16. Thereafter, as illustrated in FIG. 10D, the outer leads 16 exposed from the resin part 33 are bent downward, so that tip ends of the outer leads 16 can be used as external connection terminals.

In the semiconductor device 3, because the lower surface 10b of the die pad 10 is exposed from the resin part 33, it is possible to improve the heat dissipation.

Further, because the die pad 10 of the semiconductor device 3 is formed from one singulation region 7 of the lead frame 1, it is possible to improve the flatness of the lower surface 10b of the die pad 10 as described above. Hence, it is possible to reduce the possibility of the resin part 33 leaking toward the lower surface 10b of the die pad 10 when encapsulating the semiconductor chip 31 or the like by the resin part 33.

### Modifications of First Embodiment

Modifications of the first embodiment relate to examples of the semiconductor device in which the lead frame has a shape different from that of the embodiment described above. In the modifications of the first embodiment, a description of the constituent elements that are the same as those of the embodiment described above may be omitted.

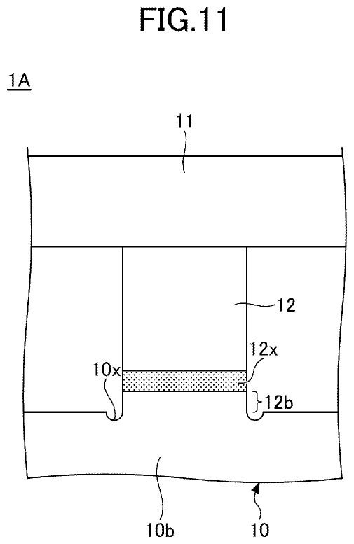

FIG. 11 is a partial bottom view illustrating an example of the lead frame according to a first modification of the first embodiment. FIG. 11 illustrates a part corresponding to the part illustrated in FIG. 5. A lead frame 1A illustrated in FIG. 11 differs from the lead frame 1 illustrated in FIG. 5, in that the position of the groove 12x in the lead frame 1A is different from that of the lead frame 1 illustrated in FIG. 5. In FIG. 11, the groove 12x is illustrated by a dot pattern for the sake of convenience.

In the lead frame 1A, the end portion of the groove 12x beside the die pad 10 in the bottom view is located at a position separated from the side forming the outer edge of the die pad 10 to which the connecting parts 12 are connected. That is, the end portion of the groove 12x beside the die pad 10 does not make contact with the side forming the outer edge of the die pad 10, and is located at the position closer to the ground ring 11 than the position of the groove 12x illustrated in FIG. 5 is to the ground ring 11.

Accordingly, the groove 12x can be arranged according to the position where the bending process is to be performed. In the case of the lead frame 1A, the connecting part 12 is also bent toward the upper surface 10a of the die pad 10 at the end portion of the groove 12x beside the die pad 10, for example. For this reason, a region 12b of the lower surface of the connecting part 12, located closer to the die pad 10 than the groove 12x of the connecting part 12 is to the die pad 10, coincides with the lower surface 10b of the die pad 10.

FIG. 12 is the bottom view illustrating an example of the semiconductor device according to the first modification of the first embodiment. A semiconductor device 3A is manufactured using the lead frame 1A according to the first modification of the first embodiment. In the semiconductor device 3A, in addition to the lower surface 10b of the die pad 10, the region 12b of the lower surface of the connecting part 12 is also exposed from the resin part 33. For this reason, it is possible to further improve the heat dissipation. In FIG. 12, the resin part 33 is illustrated by a dot pattern for the sake of convenience.

FIG. 13A and FIG. 13B are diagrams illustrating an example of the semiconductor device according to a second modification of the first embodiment. FIG. 13A is a bottom view, and FIG. 13B is a cross sectional view taken along a line C-C in FIG. 13A. In FIG. 13A, although the lead frame is illustrated as if the shape of the lead frame is visible through the resin part 33 for the sake of convenience, only the lower surface 10b of the die pad 10 is actually exposed from the resin part 33 at a lower surface of a semiconductor device 3B.

In the semiconductor device 3B illustrated in FIG. 13A and FIG. 13B, the support bars 13 are connected to the four corners of the die pad 10, respectively. Each support bar 13 is provided with a groove 13x opening toward the lower surface 10b of the die pad 10. The support bar 13 is bent toward the upper surface 10a of the die pad 10 at the end portion of the groove 13x beside the die pad 10, for example. The groove 13x is covered with the resin part 33.

In the case of the structure illustrated in FIG. 13A and FIG. 13B, it is also possible to improve the flatness of the lower surface 10b of the die pad 10, and thus reduce the possibility of the resin part 33 leaking toward the lower surface 10b of the die pad 10.

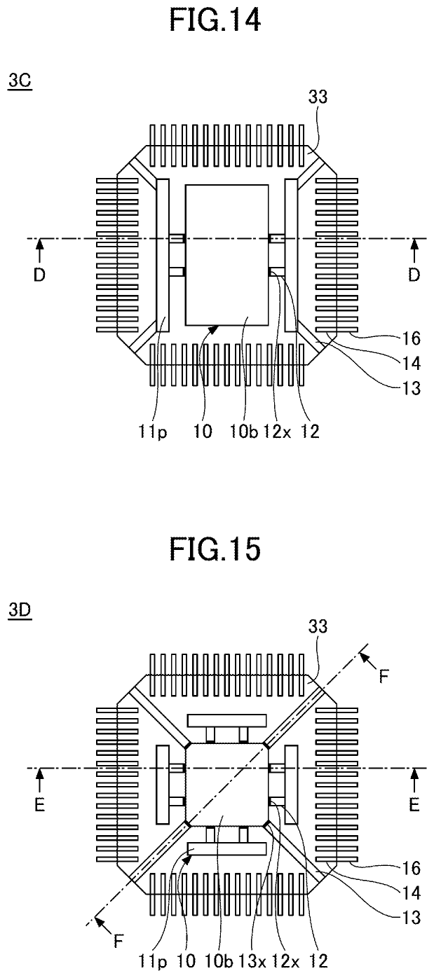

FIG. 14 is a bottom view illustrating an example of the semiconductor device according to a third modification of the first embodiment. In FIG. 14, although the lead frame is illustrated as if the shape of the lead frame is visible through the resin part 33 for the sake of convenience, only the lower surface 10b of the die pad 10 is actually exposed from the resin part 33 at a lower surface of a semiconductor device 3C. Because a cross section taken along a line D-D in FIG. 14 has the same structure as that illustrated in FIG. 8B, an illustration of this cross section will be omitted.

In the semiconductor device 3C illustrated in FIG. 14, the die pad 10 has a rectangular shape in the bottom view. In the bottom view, a ground bar 11p having an approximately rectangular shape is arranged outside and along each long side of the die pad 10, with a predetermined gap from the long side of the die pad 10. The die pad 10 and the ground bar 11p are connected to each other by the plurality connecting parts 12 arranged at predetermined intervals. In the bottom view, one end of the connecting part 12 is connected to a portion of a long side forming the outer edge of the die pad 10, and the other end of the connecting part 12 is connected to a side of the ground bar 11p beside the die pad 10. The support bars 13 extend outward from vicinities of the corners at both ends of the ground bar 11p, respectively.

Each connecting part 12 is provided with a groove 12x that opens toward the lower surface 10b of the die pad 10. The connecting part 12 is bent toward the upper surface 10a of the die pad 10 at the end portion of the groove 12x beside the die pad 10, for example. The groove 12x is covered with the resin part 33.

In the case of the structure illustrated in FIG. 14, it is also possible to improve the flatness of the lower surface 10b of the die pad 10, and thus reduce the possibility of the resin part 33 leaking toward the lower surface 10b of the die pad 10.

FIG. 15 is the bottom view illustrating an example of the semiconductor device according to a fourth modification of the first embodiment. In FIG. 15, although the lead frame is illustrated as if the shape of the lead frame is visible through the resin part 33 for the sake of convenience, only the lower surface 10b of the die pad 10 is actually exposed from the resin part 33 at a lower surface of a semiconductor device 3D. Because a cross section taken along a line E-E in FIG. 15 has the same structure as that illustrated in FIG. 8B, an illustration of this cross section will be omitted. In addition, because a cross section taken along a line F-F in FIG. 15 has the same structure as that illustrated in FIG. 13B, an illustration of this cross section will be omitted.

In the bottom view of the semiconductor device 3D illustrated in FIG. 15, the ground bar 11p having an approximately rectangular shape is arranged outside and along the side forming the outer edge of the die pad 10, with a predetermined gap from the side of the die pad 10. The die pad 10 and the ground bar 11p are connected to each other by the plurality of connecting parts 12 arranged at predetermined intervals. In the bottom view, one end of the connecting part 12 is connected to a portion of the side forming the outer edge of the die pad 10, and the other end of the connecting part 12 is connected to a side of the ground bar 11p beside the die pad 10.

Each connecting part 12 is provided with a groove 12x that opens toward the lower surface 10b of the die pad 10. The connecting part 12 is bent toward the upper surface 10a of the die pad 10 at the end portion of the groove 12x beside the die pad 10, for example. The groove 12x is covered with the resin part 33.

The support bars 13 are connected to the four corners of the die pad 10, respectively. Each support bar 13 is provided with a groove 13x opening toward the lower surface 10b of the die pad 10. The support bar 13 is bent toward the upper surface 10a of the die pad 10 at the end portion of the groove 13x beside the die pad 10, for example. The groove 13x is covered with the resin part 33.

In the case of the structure illustrated in FIG. 15, it is also possible to improve the flatness of the lower surface 10b of the die pad 10, and thus reduce the possibility of the resin part 33 leaking toward the lower surface 10b of the die pad 10.

FIG. 16A and FIG. 16B are diagrams illustrating an example of the semiconductor device according to a fifth modification of the first embodiment. FIG. 16A is the bottom view, and FIG. 16B is a cross sectional view taken along a line G-G in FIG. 16A. In FIG. 16A and FIG. 16B, although the lead frame is illustrated as if the shape of the lead frame is visible through the resin part 33 for the sake of convenience, only the lower surface 10b of the die pad 10 is actually exposed from the resin part 33 at a lower surface of a semiconductor device 3E. Because a cross section taken along a line H-H in FIG. 16A has the same structure as that illustrated in FIG. 13B, an illustration of this cross section will be omitted.

In the bottom view of the semiconductor device 3E illustrated in FIG. 16A, the bend part 17 is connected to the side forming the outer edge of the die pad 10. In the bottom view, one end of the bend part 17 is connected to a portion of the side forming the outer edge of the die pad 10. By providing the bend part 17, it is possible to improve the adhesion between the resin part 33 and the die pad 10.

Each bend part 17 is provided with a groove 17x that opens toward the lower surface 10b of the die pad 10. The bend part 17 is bent toward the upper surface 10a of the die pad 10 at the end portion of the groove 17x beside the die pad 10, for example. The groove 17x is covered with the resin part 33.

The support bars 13 are connected to the four corners of the die pad 10, respectively. Each support bar 13 is provided with a groove 13x opening toward the lower surface 10b of the die pad 10. The support bar 13 is bent toward the upper surface 10a of the die pad 10 at the end portion of the groove 13x beside the die pad 10, for example. The groove 13x is covered with the resin part 33.

In the case of the structure illustrated in FIG. 16A and FIG. 16B, it is also possible to improve the flatness of the lower surface 10b of the die pad 10, and thus reduce the possibility of the resin part 33 leaking toward the lower surface 10b of the die pad 10.

According to the embodiments and modifications of the present disclosure, it is possible to improve a flatness of a die pad in a lead frame having a curved part connected to an outer edge of the die pad.

Various aspects of the subject-matter described herein may be set out non-exhaustively in the following numbered clauses:

1. A method for manufacturing a lead frame, comprising:
forming a patterned metal plate by performing a metal plate machining, the patterned metal plate including a frame, a die pad having an upper surface and a lower surface and arranged inside the frame in a bottom view, and a curved part disposed outside the die pad in the bottom view and having one end connected to an outer edge of the die pad;
forming a groove in the curved part, the groove opening toward the lower surface of the die pad; and
bending the patterned metal plate,
wherein the bending bends the curved part at the groove toward the upper surface of the die pad.

2. The method for manufacturing the lead frame according to clause 1, wherein the groove is formed during the forming the patterned metal plate.

Although the modifications are numbered with, for example, “first,” “second,” or “third,” “fourth,” or “fifth,” the ordinal numbers do not imply priorities of the modifications. Many other variations and modifications will be apparent to those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A lead frame comprising:
a die pad having an upper surface and a lower surface; and
a curved part disposed outside the die pad in a bottom view, and having one end connected to an outer edge of the die pad, wherein
the curved part has a groove that opens toward the lower surface of the die pad, and
the curved part is curved toward the upper surface of the die pad at the groove.

2. The lead frame as claimed in claim 1, wherein the curved part is curved toward the upper surface of the die pad at an end portion of the groove beside the die pad.

3. The lead frame as claimed in claim 1, wherein an end portion of the groove beside the die pad, in the bottom view, is located on a side of the die pad to which the curved part is connected.

4. The lead frame as claimed in claim 1, wherein an end portion of the groove beside the die pad, in the bottom view, is located at a position separated from a side of the die pad to which the curved part is connected.

5. The lead frame as claimed in claim 4, wherein a region of a lower surface of the curved part located closer to the die pad than to the groove coincides with the lower surface of the die pad.

6. The lead frame as claimed in claim 1, further comprising:
a recess that is recessed toward a center of the die pad and is provided on both sides of a region connected to the curved part in the bottom view, on a side of the die pad.

7. The lead frame as claimed in claim 1, comprising:
a plurality of curved parts,
wherein the groove is provided in each of the plurality of curved parts.

8. A semiconductor device comprising:
a die pad having an upper surface and a lower surface;
a curved part disposed outside the die pad in a bottom view, and having one end connected to an outer edge of the die pad;
a semiconductor chip mounted on the upper surface of the die pad; and
a resin part encapsulating the semiconductor chip, wherein
the curved part has a groove that opens toward the lower surface of the die pad, and is curved toward the upper surface of the die pad at the groove, and
the lower surface of the die pad is exposed from the resin part.

9. The semiconductor device as claimed in claim 8, wherein the groove is covered with the resin part.
